(19) United States
(12) Patent Application Publication
(10) Pub. No.: US 2003/0222691 A1
(43) Pub. Date: Dec. 4, 2003

(54) Broadband phase-shifter

(76) Inventors: Philippe Dueme, Orsay (FR); Ronald Funck, Port Marly (FR)

Correspondence Address: LOWE HAUPTMAN GILMAN & BERNER, LLP, 1700 DIAGNOSTIC ROAD, SUITE 300, ALEXANDRIA, VA, 22314, US

(21) Appl. No.: 10/318,376

(22) Filed: Dec. 13, 2002

(30) Foreign Application Priority Data
Dec. 14, 2001 (FR) 01 16159

(51) Int. Cl. H03K 3/00

(52) U.S. Cl. 327/231

(57) ABSTRACT

A broad-band phase-shifter comprises at least one selector switch and one elementary phase-shifter with two parallel channels, each comprising n “all-pass” cells. The selector switch routes the input signal (E) to either of the channels, each cell phase-shifting a signal according to a law as a function of its frequency, the phase shift Δφ produced by an elementary phase-shifter being obtained by switching the signal from one channel to the other. The device can be applied especially in electronically scanned antennas.

### BACKGROUND OF THE INVENTION

The present invention relates to a broadband phase-shifter. It can be applied especially to electronically scanned antennas. More generally, it can be applied to all the microwave devices requiring a phase shift over a very broad frequency band.

The use of phase-shifters in electronically scanned antennas is known. An electronically scanned antenna comprises an array of electronically controllable phase-shifter cells. Each phase-shifter cell comprises a microwave phase-shifter controlled for example on several bits. For example, a phase-shifter controlled by two bits may give 0°, 90°, 180° and 270° phase shifts.

The making of phase-shifters working in broad frequency bands is also known. To cover a given band, these phase-shifters generally comprise an association of phase-shifters working in sub-bands. There then arises a problem of space requirement, cost, consumption and even gain losses.

More generally, in the market, there are no MMIC type phase-shifters in integrated circuit form that cover the totality of a useful operating band when this band goes beyond a certain width. It is indeed difficult to find phase-shifters or combinations of phase-shifters that cover both the X band and frequencies below 3 GHz at the same time. This is especially due to the fact that this type of phase-shifter uses couplers called Lange couplers whose frequency band cannot extend to a ratio of more than 3 between maximum and minimum frequencies, and whose size becomes prohibitive toward the 2 GHz range. However, the losses in these phase-shifters are relatively low. Furthermore, these circuits occupy relatively large surface areas.

### SUMMARY OF THE INVENTION

It is an aim of the invention to overcome the above-mentioned drawbacks, especially to enable the making of a phase-shifter that works in a broad frequency band without necessitating, especially, the association of phase-shifters working in sub-bands. To this end, an object of the invention is a device for the phase-shifting of a signal comprising at least one selector switch and one elementary phase-shifter having two parallel channels A, B each having n “all-pass” cells. The selector switch routes the input signal toward either of the channels, each cell phase-shifting a signal according to a law that is a function of its frequency. The phase-shift Δφ produced by an elementary phase-shifter is obtained by switching over the signal from one channel to the other, and is equal to the difference between the phases of the two channels.

To obtain several phase-shift values, the device comprises several cascade-connected elementary phase-shifters, each separated by a four-state 2-to-2 selector switch and the phase-shift Δφ from one elementary phase-shifter to the next one varies for example by a φ/2^{N} step.

Advantageously, to ensure a substantially constant phase-shift for an elementary phase-shifter on a broad frequency band, the inductors of the “all-pass” cells” are related by a mutual inductance. Advantageously, the inductors may be formed by spirals and the mutual inductance may be formed by the interleaving or imbrication of these spirals.

### BRIEF DESCRIPTION OF THE DRAWINGS

Other features and advantages of the invention shall appear from the following description, made with reference to the appended drawings, of which:

FIG. 1 shows a cell known as an “all-pass” cell;

FIG. 2, illustrates the phase shift produced on a signal passing into an “all-pass” cell as a function of the frequency of this cell;

FIG. 3 shows a first exemplary phase-shifter formed by two channels each comprising an “all-pass” cell;

FIG. 4 illustrates the phase-shift between the first cells of each of the two channels of the previous phase-shifter, on a frequency band;

FIG. 5 shows a second exemplary phase-shifter where each of the two channels comprises two “all-pass” cells;

FIG. 6, illustrates the phase shift between the two channels of the previous phase-shifter on a broadened frequency band;

FIGS. 7a to 7d, illustrate the phase shift as a function of the frequency for certain values of mutual inductance within “all-pass” cells;

FIG. 8 shows a possible embodiment, in the form of interconnected spirals, of the inductors of an “all-pass” cell;

FIGS. 9a and 9b show two other possible exemplary embodiments of the inductors in spiral form;

FIG. 10 shows an exemplary embodiment of an elementary phase-shifter comprising two parallel channels of “all-pass” cells;

FIG. 11 is a table indicating several exemplary phase-shift values as a function of the values of the components of the different “all-pass” cells forming the phase-shifter;

FIG. 12, shows an exemplary phase-shifter formed by several elementary phase-shifters and selector switches;

FIG. 13 is a curve representing the power of a signal crossing the phase-shifter.

### MORE DETAILED DESCRIPTION

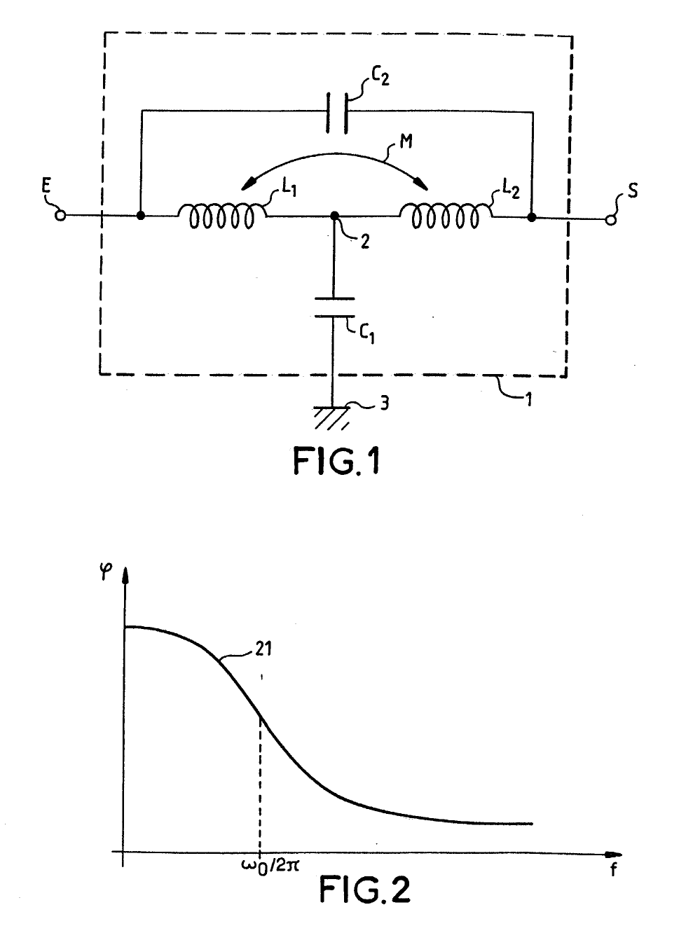

FIG. 1 presents a cell 1, known as an “all-pass” cell, based on capacitors and inductors. This cell has two series-connected inductors L₁, L₂. A first capacitor C₁ is connected between the midpoint 2 of the two inductors and a reference potential 3, for example the ground potential. The input E of the cell is connected to a pole of the first inductor L₁ and the output S of the cell is connected to a pole of the second inductor L₂. A bridge capacitor C₂ connects the input E to the output S. The inductors L₁, L₂ have, for example, the same inductance value L. Between them, they have a mutual inductance M. The relative value m of this mutual inductance is given by the following relationship:

$$m = \sqrt{\frac{{M}^{2}}{{L}_{1} {L}_{2}}} \qquad ( 1 )$$

the inductance values being identified with the notations of these components L₁, L₂ and M.

In FIG. 2, a curve 21 illustrates the phase shift (p induced on a microwave signal passing in the cell 1. The cell phase-shifts this signal according to a relationship represented by the curve 21, as a function of the frequency f of this signal. Such a cell has no cut-off frequency in terms of gain (modulus of the transfer function) but in effect prompts a phase shift of the signals. After remaining constant in a low-frequency band, the phase shift φ diminishes as a function of the frequency and gets stabilized asymptotically at a constant value at the high frequencies. It is possible to define a transition angular frequency on ω₀ at the center of the transfer zone of the phase, defined by the following relationship:

$${ω}_{0} = \sqrt{\frac{1 + {k}^{2}}{LC}} \qquad ( 2 )$$

k being an adjusting parameter ranging from 0 to 1.

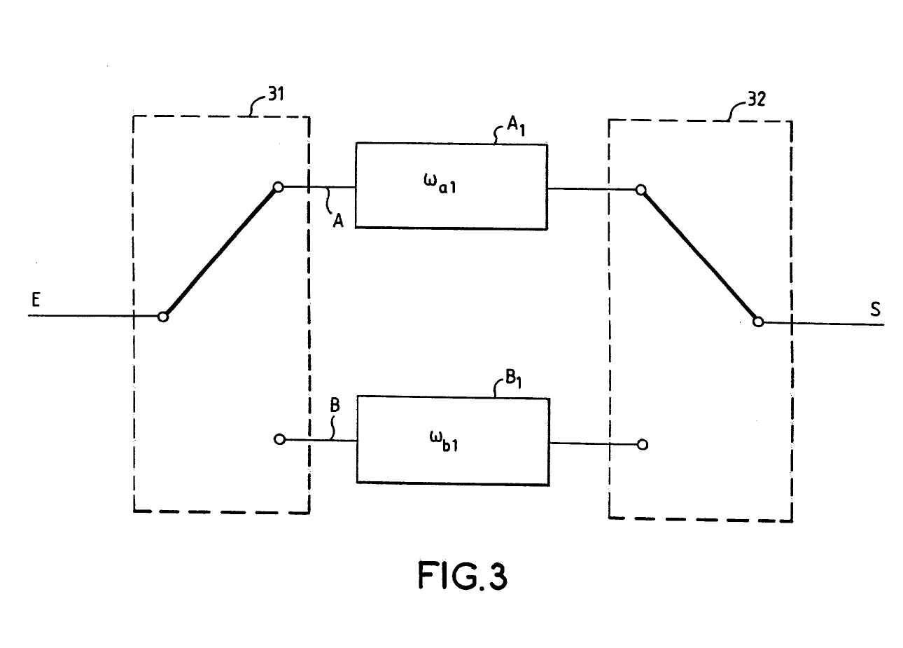

FIG. 3 is a block diagram illustrating a first exemplary phase-shifter according to the invention. This phase-shifter consists of “all-pass” cells. A circuit of this kind comprises two parallel channels each comprising a cell of the type shown in FIG. 1. In this case, the phase-shifter comprises two cells A₁, B₁ having transition angular frequencies respectively referenced ωₐ₁, ωₐ₂. A first selector switch 31 routes the input signal E to one channel or the other. A second selector switch 32, or output selector switch, routes the channel conveying the signal to the output S of the phase-shifter. These selector switches 31, 32 may be active, i.e. based on components amplifying the energy level of the signal to be switched, or they may be passive. The active selector switches are, for example, distributed-structure switches formed by cells fitted out with cascode-connected transistors.

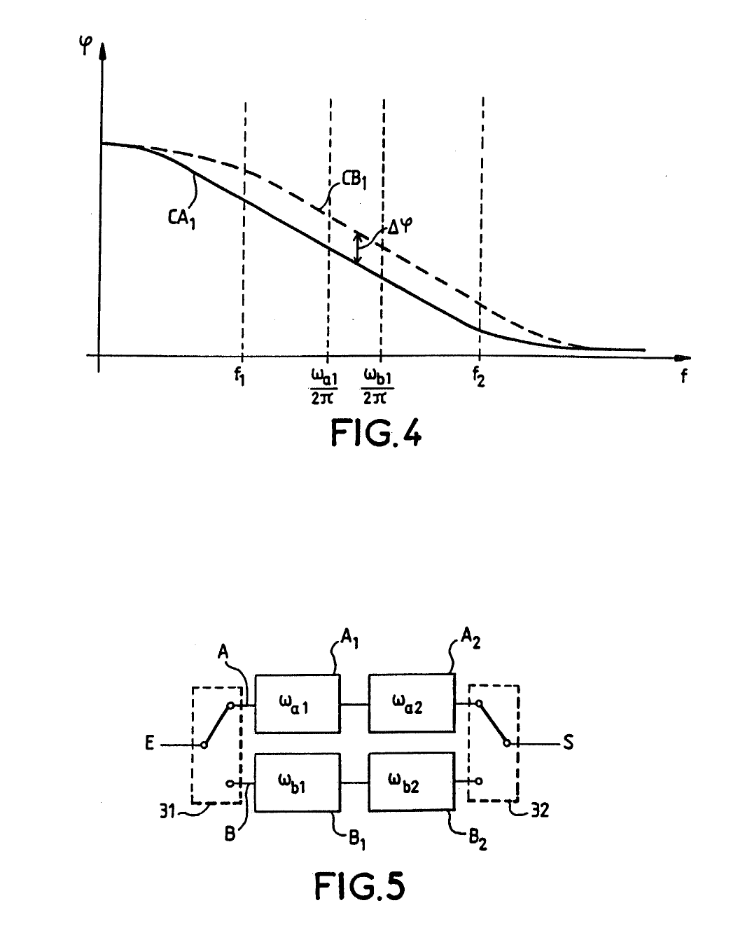

FIG. 4 shows two curves of phase shifts CA₁ and CB₁ corresponding respectively to the cell A₁ of the first channel, hereinafter called the channel A, and the cell B₁ of the second channel, hereinafter called the channel B. The two curves are offset from each other and parallel on a frequency band [f₁, f₂]. The difference between these two curves is obtained by modulating the parameters of the cells A₁, B₁, especially the values of the capacitors C₁, C₂ and of the inductors L₁, L₂ of each cell. The offset Δφ between these two curves is the phase shift applied to an incoming signal when it is switched from one path to the other. This offset Δφ represents the phase shift between the two channels A and B. The phase shift Δφ of a signal is therefore obtained by switching it over from one channel to the other, for example from the channel B to the channel A. Arbitrarily, the channel B may be taken, for example, as the reference, i.e. as corresponding to a zero differential phase shift.

In FIG. 5, a block diagram illustrates a second exemplary phase-shifter according to the invention. This phase-shifter is again formed by “all-pass” cells distributed on two channels in parallel. Each channel comprises, in series, n cells of the type shown in FIG. 1, two in the case of FIG. 5. In this case, the phase-shifter therefore comprises four cells A₁, A₂, B₁, B₂ having transition angular frequencies respectively referenced ωₐ₁, ωₐ₂, ω_{b1}, ω_{b2}. As in the above example, a first selector switch 31 routes the input signal E to one channel or the other. A second selector switch 32, or output selector switch, routes the channel conveying the signal to the output S of the phase-shifter. These selector switches 31, 32 may be active or passive.

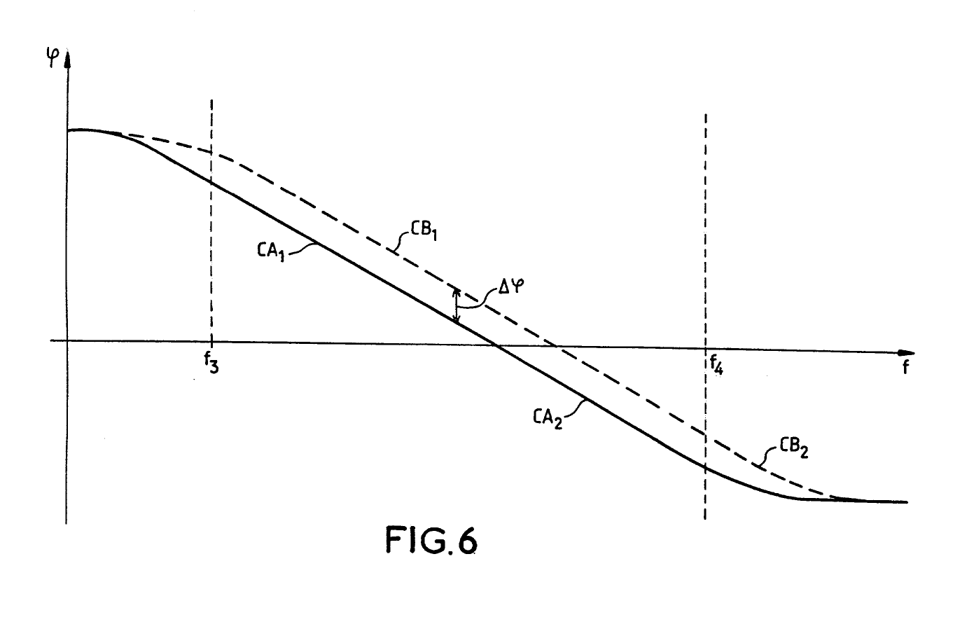

FIG. 6 shows the case where all the four cells A₁, A₂, B₁, B₂ of the phase-shifter are taken into account. The second cells A₂, B₂ of the channels A and B enable the operating band of the phase-shifter to be augmented. In particular, the parameters of the cell A₂ are defined so that the corresponding phase-shift curve CA₂ is a prolongation of the phase-shift curve CA₁ of the first cell A₁. Similarly, on the channel B, the parameters of the cell B₂ are defined so that the corresponding phase-shift curve CB₂ is the prolongation of the phase-shift curve CB₁ of the first cell B₁. In reality, each cell nevertheless acts on the entire frequency band.

The four-cell phase-shifter A₁, A₂, B₁, B₂ then works in a frequency band [f₃, f₄], where f₃<f₁ and f₄>f₂, f₁ and f₂ being the frequencies delimiting the band [f₁, f₂] defined here above with reference to FIG. 4. This band is broadened on either side.

The phase shift Δφ between the two channels is given by the following relationship:

$$\begin{matrix}\begin{matrix}Δ ϕ = 4 [ arctg ( \frac{pq}{k} - \frac{1}{kpq} ) + arctg ( \frac{p}{kq} - \frac{q}{kp} ) ] \\ \begin{matrix}with & {p}^{2} = \frac{{ω}_{a1}}{{ω}_{b1}} = \frac{{ω}_{a2}}{{ω}_{b2}} & and & {q}^{2} = \frac{{ω}_{a2}}{{ω}_{a1}} = \frac{{ω}_{b2}}{{ω}_{b1}}\end{matrix}\end{matrix} \\ \begin{matrix}and & k = \sqrt{\frac{1 - m}{1 + m}}\end{matrix}\end{matrix} \qquad ( 3 )$$

where m is the value of the relative mutual inductance as defined here above by the relationship (1); m ranges from 0 to 1.

Since the equation given by the relationship (2) cannot be directly resolved, a computation program may be used for example to determine the theoretical elements p and q to obtain a given phase shift Δφ and a given coefficient of mutual inductance m. From this, we deduce the frequencies or transition angular frequencies ωₐ₁, ωₐ₂, ω_{b1}ω_{b2} of each of the cells and hence of the values of their parameters or components L₁, L₂, C₁, C₂. The relationship (2) shows that the phase shift Δφ depends especially on the parameter k and hence on the value m of the mutual inductance. This phase shift Δφ also depends on the frequency of the signal to which it is applied. It is possible to further increase the band [f₃, f₄] with n>2. In this case, however, the equations become more complicated.

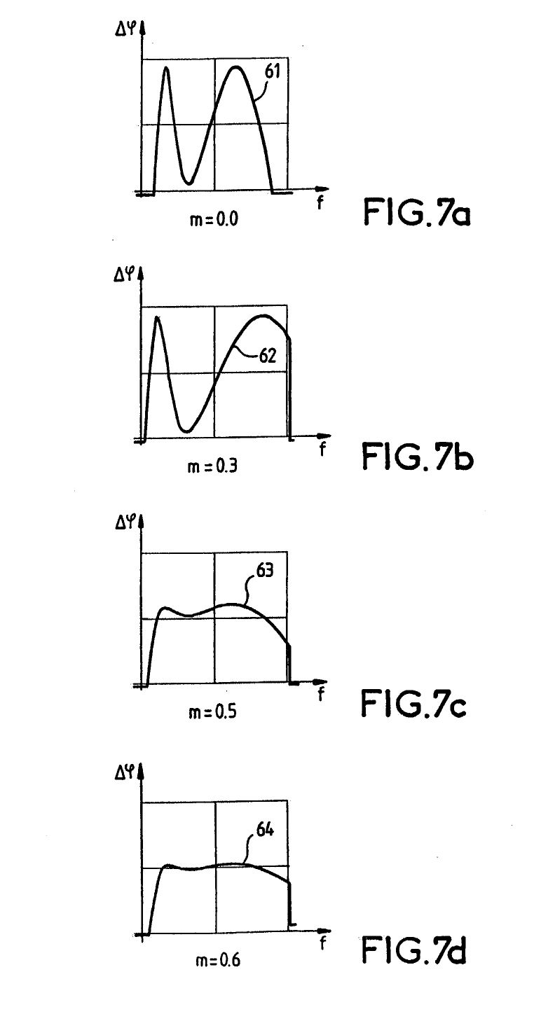

FIGS. 7a to 7d show this phase shift Δφ as a function of the frequency for certain values of relative mutual inductance m, and for ideal parameters L₁, L₂, C₁, C₂, supposed to be given, of the phase-shift curves CA₁, CA₂, CB₁, CB₂ as illustrated in FIG. 6. As an example, referring to the relationship (1),

$$m = \frac{M}{{L}_{1}} ,$$

i.e. L₁=L₂. These curves are substantially parallel and hence the phase shift is substantially constant. These FIGS. 7a to 7d highlighted by the Applicant will show the combined influence of the frequency and of the mutual inductance m on the fluctuations of the phase shift Δφ.

In particular, FIGS. 7a, 7b, 7c and 7d, plotted with a common scale and for n=2, correspond to the cases where m is respectively equal to 0.0; 0.3; 0.5 and 0.6. Should m=0, the phase shift as a function of the frequency is represented by a highly fluctuating curve 61, reflecting a phase shift Δφ that similarly varies as a function of the frequency. The greater the increase in the mutual inductance value m, the smaller appear to be the fluctuations of the curves 62, 63, 64. More particularly, for m=0.6 for example, the curve 64 representing the phase shift Δφ remains substantially constant over a relatively broad frequency band. This corresponds to a better parallelism of the curves CA₁, CA₂ and CB₁, CB₂ on this frequency band. FIGS. 6a to 6d show the value of obtaining the greatest possible mutual inductance value m. The value m=0.6 is approximately the greatest maximum value that can be obtained in practice by using the imbricated spiral technique. An improvement by a value m>0.6 can be imagined in using, for example, spirals that are superimposed with several metal levels.

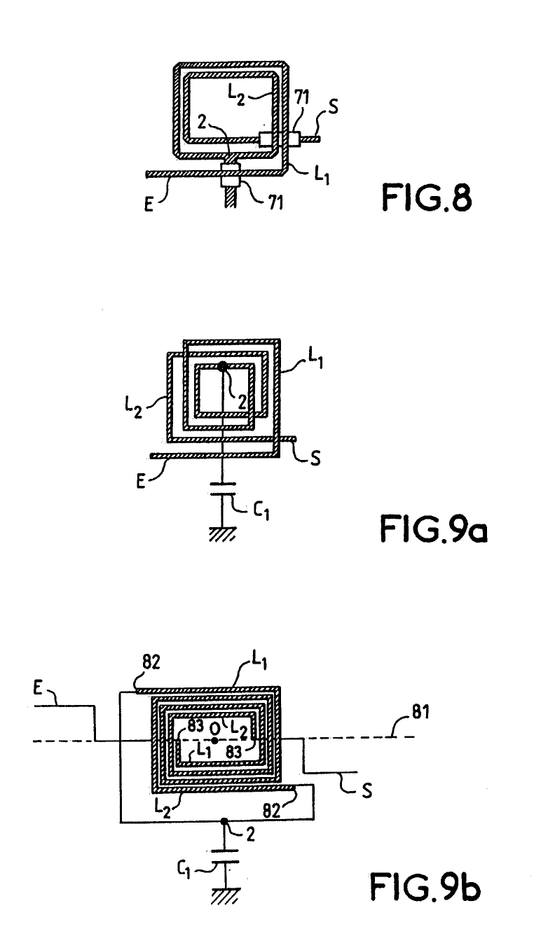

FIG. 8 shows a possible exemplary embodiment of the two inductors L₁, L₂ of an all-pass cell 1 that is used to obtain a relatively high mutual inductance m between these two inductors. This is achieved by means of a strong coupling between these two inductors L₁, L₂. These are imbricated spirals. A first spiral, formed between the input E and the midpoint 2 constitutes the first inductor L₁ and a second spiral formed between this midpoint 2 and the output S, imbricated in the first turn, forms the second inductor L₂. These spirals are, for example, conductive tracks made on a substrate. These tracks may be made of gold and the substrate may be made of gallium arsenide (GaAs). In the case of FIG. 8, the spirals are formed, for example, by a turn each. The turns may be circular or square-shaped. Since the spirals are imbricated, the tracks may intersect. Insulation means 71 are then positioned between the overlapping parts of the track.

FIGS. 9a and 9b show other possible exemplary embodiments of the inductors L₁, L₂, again formed, for example, by spiral tracks made on a substrate. In the case of FIG. 9a, the spirals are again imbricated but one is no longer contained in the other. They are offset with respect to each other. This makes it possible, in particular, to obtain efficient coupling between the inductors, hence a relatively high value m while keeping the two spirals at identical lengths and hence keeping substantially identical inductance values for L₁, L₂. FIG. 9b shows another embodiment that can be used to obtain efficient coupling and identical inductance values. The two spirals L₁, L₂ are imbricated in each other and positioned symmetrically with respect to an axis 81. They are, for example, even symmetrical with respect to a point O located on this axis 81. Each spiral L₁, L₂ has an inner end 83, positioned inside with respect to both spirals, and an outer end 82. The outer ends 82 are connected to the midpoint 2 which is itself connected to the capacitor C₁. The inner end 83 of the first spiral L₁ is connected to the input E and the inner end 83 of the second spiral L₂ is connected to the output S.

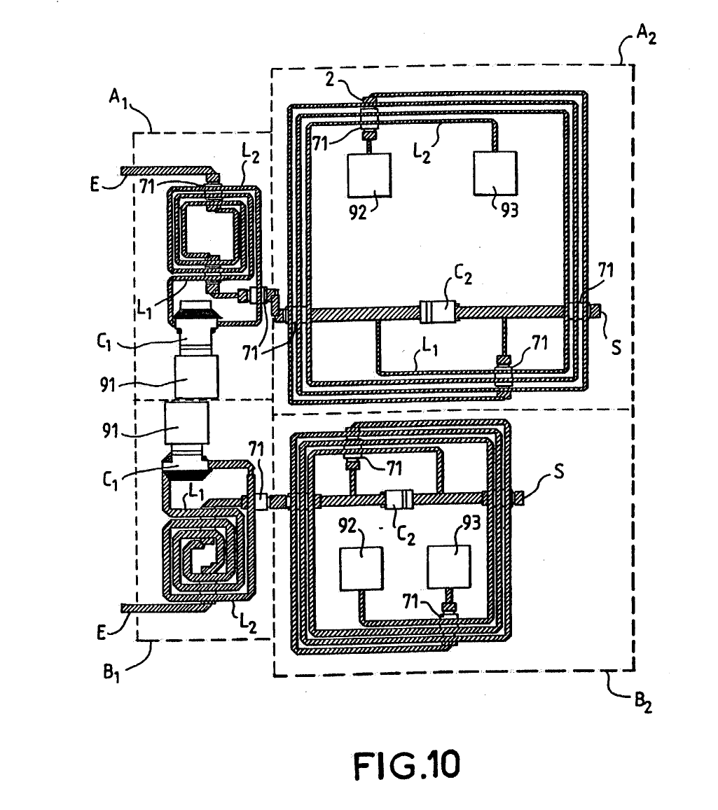

FIG. 10 shows a possible exemplary embodiment of a phase-shifter according to the invention, according to the block diagram of FIG. 5 comprising two channels of two all-pass cells, the selector switches 31, 32 being not shown. This phase-shifter has four all-pass cells A₁, A₂, B₁, B₂ whose inductors are constituted by spirals, for example of the same type as those of FIGS. 8, 9a and 9b. Each cell A₁, A₂, B₁, /B₂ therefore comprises at least two inductors L₁, L₂ in the form of imbricated spirals. For reasons of reading facility, the first inductor is referenced L₁ in each cell, although its value and shape may be different from one cell to another. This is also the case for the second inductor L₂ as well as for the ground capacitors C₁ and the bridge capacitors C₂.

The cells A₁ and B₁ each comprise two inductors L₁, L₂ made, for example, according to the model of FIG. 7. The first inductor L₁ is connected to the input E of the cell A₁, B₁. The capacitor C₁, connected to the junction point of the inductors L₁, L₂ is furthermore connected to the ground potential by a metallized hole 91. There is no bridge capacitor C₂ connecting the input to the output of the cell. In particular, the stray capacitances are sufficient to produce a capacitance of minimum value. To create a phase shift Δφ between the two A₁, B₁, the parameters defining the inductance values and the capacitance C₁ are adjusted. These parameters may be, for example, the length of the spirals or the width of the tracks to define the inductance values and, classically, the dimensions of the capacitor C₁ to define its capacitance.

The cells A₂, B₂ have a similar structure but with highly different inductance and capacitance values, and hence with very different geometrical parameters. In particular, the values of the inductors L₁, L₂ are greater than those of the cells A₁, B₁. To this end, their turns are greater. For these cells A₂, B₂, there is a bridge capacitor C₂, connecting the input to the output of the cell, but no capacitor C₁ , connecting the junction point 2 of the inductors to the ground. This corresponds to an infinite capacitance value. Each inductor L₁, L₂ therefore has one end directly connected to the ground, for example by means of a metallized hole 92, 93, one of them L₁ having its other end connected to the input of the cell and the other inductor L₂ having its other end connected to the output of the cell. This cell is connected to the input of the output selector switch 32. As in the case of the cells A₁, B₁, the invention, for example, modulates the geometrical parameters defining the inductance and capacitance values to carry out a given phase shift Δφ, which approximately is preferably the same as the one existing between these cells A₁, B₁. The phase shift curves CA₂, CB₂ corresponding to the cells A₂, B₂ prolong the phase shift curves CA₁, CB₁ corresponding to the cells A₁, B₁. In the exemplary embodiment of FIG. 10, the inductors L₁, L₂ of the cells A₁, B₁ , have a lower value than the inductors L₁, L₂ of the cells A₂, B₂. The result thereof is that the transition angular frequencies ωₐ₁, ω_{b1}, of the cells A₁, B₁ are greater than the transition angular frequencies ωₐ₂, ω_{b2} of the cells A₂, B₂. The curves CA₁, CB₁ are therefore situated in the high frequency band and the curves CA₂, CB₂ are therefore situated in a lower frequency band so as to cover, of course, a continuous broad band [f₃, f₄]. In other words, and as a first approximation, the cells A₁, B₁ phase-shift the signals at high frequencies and the cells A₂, B₂ phase-shift the signals at low frequencies. For reasons of simplicity of implementation especially, the capacitor C₂ is no longer formed in the cells A₁, B₁ and the capacitor C₁ is no longer formed in the cells A₂, B₂. This corresponds to an exemplary embodiment. It is of course possible to make the two capacitors C₁, C₂ in these cells.

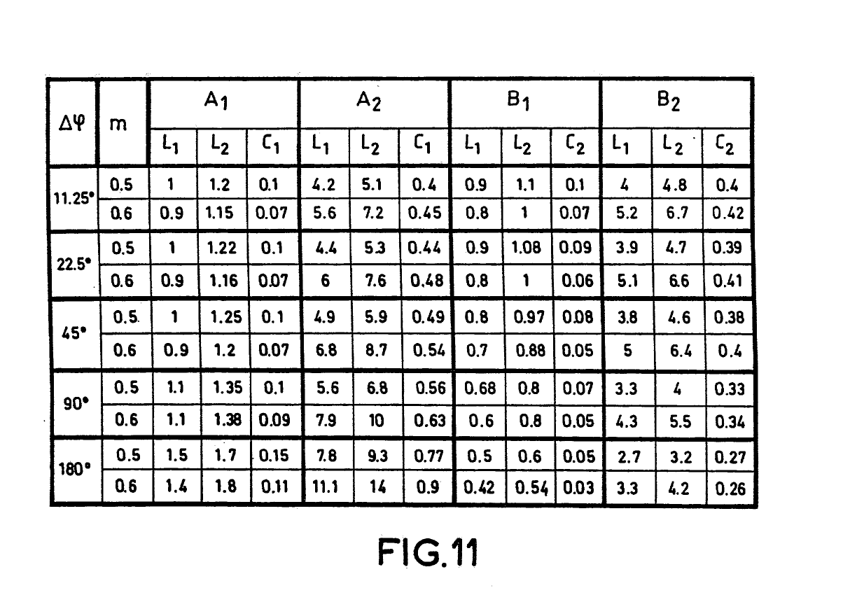

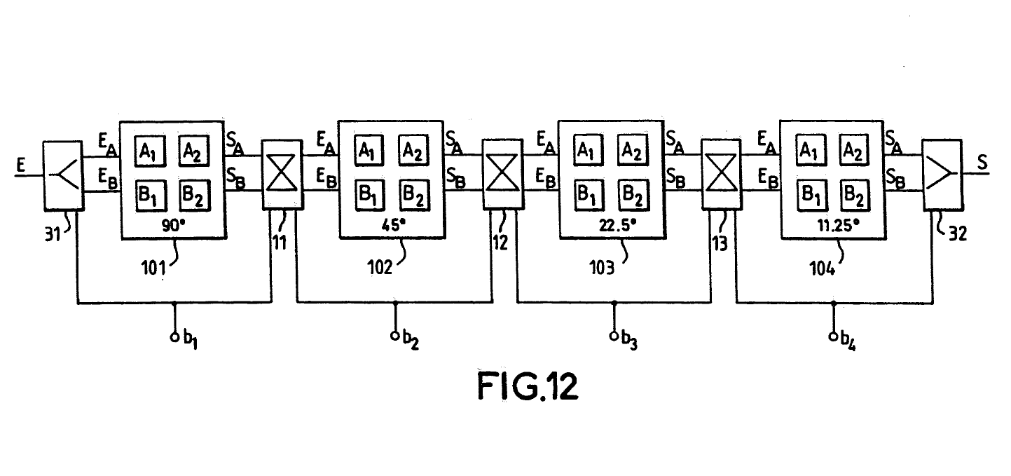

FIG. 11 shows a table, by way of an example, indicating several phase-shift values Δφ as a function of the values of the components L₁, L₂, C₁, C₂ of the cells of FIG. 9, and as a function of the value of the relative mutual inductance m resulting from the imbrication of the inductance values, and for a given frequency band in the microwave domain. Indeed, by playing on the parameters of the cells, i.e. essentially on the geometrical parameters of their components L₁, L₂, C₁, C₂, it is possible to obtain different values of phase shifts. The values of the inductors L₁, L₂ and of the capacitors C₁, C₂ are given in terms of relative values. In conformity with what has been described with reference to FIG. 10, it can be seen that the values of the inductors L₁, L₂ of the cells A₁, B₁ are appreciably lower than those of cells A₂, B₂. A phase-shifter of the type shown in FIG. 10, once made, can be used to obtain a single phase-shift value Δφ. This is an elementary phase-shifter with a control bit. The phase-shift values Δφ given by way of an example are 11.25°; 22.5°; 45°; 90° and 180°.

FIG. 12 shows another exemplary embodiment of a phase-shifter according to the invention. This is a four-bit phase-shifter. More particularly, it comprises four series-connected, i.e. cascade-connected, elementary phase-shifters 101, 102, 103, 104 of the type shown in FIG. 10. A first phase-shifter 101 creates a 90° phase shift, the following phase-shifters 102, 103, 104 create the respective phase shifts 45°, 22.5° and 11.25°. A selector switch 11, 12, 13 is placed between two successive elementary phase-shifters. These selector switches are 2-to-2 selector switches, i.e. their switching rule is the following, with E_{A}, E_{B} and S_{A}, S_{B} denoting the respective inputs and outputs of the channels A and B of an elementary phase-shifter:

1^{st} state: The output S_{A} of a phase-shifter is routed towards the input E_{A} of the next phase-shifter;

2^{nd} state: The output S_{B} of a phase-shifter is routed towards the input E_{B} of the next phase-shifter;

3^{rd} state: The output S_{A} of a phase-shifter is routed towards the input E_{B} of the next phase-shifter;

4^{th} state: The output S_{B} of a phase-shifter is routed towards the input E_{A} of the next phase-shifter.

The states of a selector switch of this kind are therefore controlled by two bits.

The selector switch 31 which connects the input E of the phase-shifter to the inputs E_{A}, E_{B} of the first elementary phase-shifter 101 is a 1-to-2 selector switch of the type shown in FIG. 3. The selector switch 32 which connects the outputs S_{A}, S_{B} of the last elementary phase-shifter of the sequence to the output S of the full phase-shifter is a 2-to-1 selector switch of the type shown in FIG. 3. Depending on whether the signal is present at one or the other of the outputs S_{A}, S_{B}, this selector switch connects the output S to the channel on which the signal is present. In this respect, this selector switch 32 is actually controlled by the state of the last 2-to-2 selector switch 13. This is also the case with the states of the other selector switches which depend on the states of the previous selector switches. The input selector switch 31 and output selector switch 32 are controlled by only one bit. The control bits b₁, b₂, b₃, b₄ of the circuit of FIG. 12 are therefore connected to the selector switches as follows:

The first bit b₁ controls the input selector switch 31 and the next selector switch 11;

The second bit b₂ controls this selector switch 11 and the next selector switch 12;

The third bit b₃ controls this selector switch 12 and the next selector switch 13;

The fourth bit b₄ controls this selector switch 13 and the output selector switch 32.

In this configuration, the input and output selector switches 31, 32 are truly controlled by one bit and the intermediate selector switches 11, 12, 13 are truly controlled by two bits.

A phase-shifter according to FIG. 12 is used to make all the phase shifts, ranging from 0° to 168.75° in 11.25° steps. By way of an example, a reference state can be taken where the signal goes through all the channels B of the elementary phase-shifters. The phase shift relative to this reference will be Δφ=168.75° if the signal passes through all the channels A. For example, for a 0000 encoding, the phase shift Δφ is 0°. In this case, the maximum value 168.75° is logically obtained for the 1111 encoding. The phase-shifter of FIG. 12 comprises four elementary phase-shifters. It is of course possible to envisage a phase-shifter comprising a different number of elementary phase-shifters. If this phase-shift device comprises N elementary phase-shifters, the phase shift Δφ from one elementary phase-shifter to the next one increases or decreases for example by one φ/2^{N} step, φ being a maximum reference phase shift, equal for example to 180°.

Advantageously, the switches are for example alternately active and passive. The sequences of the components of the sequence of a phase-shifter of the type shown in FIG. 12 may therefore be the following:

an active selector switch 31;

a 90° phase-shifter 101;

a passive selector switch 11;

a 45° phase-shifter 102;

an active selector switch 12;

a 22.5° phase-shifter 103;

a passive selector switch 13;

an 11.25° phase-shifter 104;

an active selector switch 32.

This solution of alternation provides in particular for an efficient compromise between the performance characteristics of the entire sequence and the size or surface area occupied by this assembly. The FIG. 12 illustrates this point.

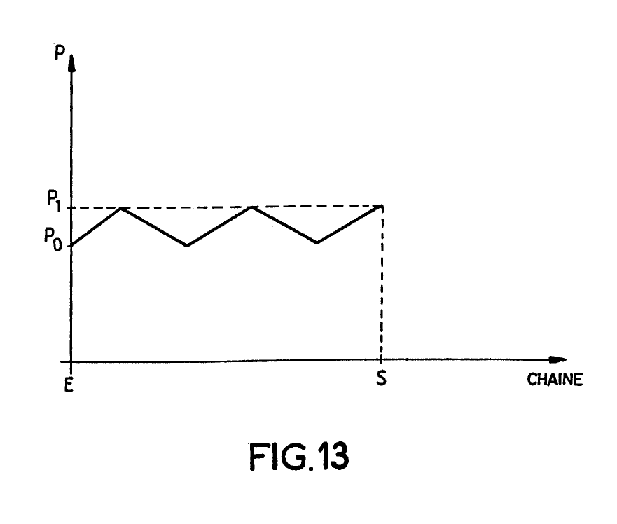

FIG. 13 shows a curve 121 representing the power conveyed by a signal as and when it moves forward in the sequence of components constituting the phase-shifter of FIG. 12, in the case of an exemplary embodiment in which the selector switches are alternately active and passive. The use of an active selector switch has the advantage especially of blocking the standing waves which could disturb the operation of the phase-shifter because the parameter S₁₂ (the return of the signal from the output to the input) is very low as compared with S₂₁. In particular, if the selector switch is passive and therefore symmetrical, it can disturb the phase-shift function inasmuch as it then induces error signals due to the leakages. It is therefore preferable to use active selector switches. The active selector switches nevertheless have a drawback. This drawback is the fact that they inherently amplify a signal that crosses them. After the signal has passed through several active selector switches, it is greatly amplified. It is then necessary to provide for a sizing of the components, namely of the selector switches themselves but also of the elementary phase-shifters, that support this increase in power thus produced. A direct consequence of sizing especially is the increase in the surface area occupied by these components, and an increase in the power consumption. This counters the goal of reducing the space requirement of the phase-shifters but also that of reducing cost and of course of reducing consumption. The alternating approach illustrated in FIG. 13 is used to comply with this goal. From the input E of the phase-shifter when a signal comprises an initial power value P₀, its power increases in the first selector switch 31, which is active, up to a power value P₁. Its power value then diminishes in the second selector switch 11 which is active and in the phase-shifter structures, and then increases again in the active selector switch following 12 and so on and so forth. The result of this is all along the sequence and after the output, the power that flows through the different components is substantially constant, providing for an efficient compromise between electrical consumption, the noise factor, the reality of the sequence and the space requirement. This power does not exceed or hardly exceeds the power P₁, and therefore remains within a permissible limit. The alternation illustrated in FIG. 13 is in active-passive-active alternation. It would naturally be possible to obtain a passive-active-passive type of alternation by placing a passive selector switch 31 at the input of the phase-shifter. However, for reasons of adaptation and noise factor, it may be preferable to start with an active selector switch 31. Any arrangement other than strict alternation remains however possible.

The exemplary embodiments presented here above comprise elementary phase-shifters: each channel A, B comprises two “all-pass” cells. It is of course possible to envisage channels comprising more than two cells, in order to further broaden the frequency band.

What is claimed is:

1. A device for the phase-shifting of a signal comprising at least one selector switch and one elementary phase-shifter (A₁, A₂, B₁, B₂) having two parallel channels (A, B) each having n “all-pass” cells, the selector switch routing the input signal (E) toward either of the channels, each cell phase-shifting a signal according to a law (CA₁, CA₂, CB₁, CB₂) that is a function of its frequency, the phase-shift Δφ produced by an elementary phase-shifter being obtained by switching over the signal from one channel to the other.

2. A device according to claim 1, wherein the components (L₁, L₂, C₁, C₂) of the cells are defined so that the curves (CA₁, CA₂) representing the phase-shift laws of the first channel (A) are parallel to the representative curves (CB₁, CB₂) of the second channel (B).

3. A device according to one of the above claims, wherein the components (L₁, L₂, C₁, C₂) of the cells are defined so that, on a channel (A, B), the representative curves (CA₁, CA₂ and CB₁, CB₂) prolong one another.

4. A device according to one of the above claims, comprising several cascade-connected elementary phase-shifters.

5. A device according to claim 4, wherein the elementary phase-shifters are connected to one another by selector switches.

6. A device according to claim 5, wherein the selector switches are four-state 2-to-2 selector switches.

7. A device according to any of the claims 4 to 6, wherein the phase shift Δφ from one elementary phase-shifter to the next one varies by a step φ/2^{N}, φ being a reference phase shift.

8. A device according to any of the claims 5 to 7, wherein the selector switches are alternately active and passive.

9. A device according to one of the above claims, wherein the first selector switch switching the input (E) to the first elementary phase-shifter is active.

10. A device according to one of the above claims, wherein an elementary phase-shifter comprises four cells, two cells A₁, A₂ in the first channel (A) and two cells B₁, B₂ in the second channel (B):
the cells A₁, B₁, comprising a ground capacitor (C₁), connected to the junction point of the inductors, and also connected to the ground potential by a metallized hole;
the cells A₂, B₂, having a bridge capacitor (C₂) connecting the input to the output of the cell, each inductor (L₁, L₂) being connected to a capacitor (C₁) furthermore connected to the ground, one inductor (L₁) having its other end connected to the input of the cell and the other inductor (L₂) having its other end connected to the output of the cell.

11. A device according to claim 10, wherein the cells A₁, B₁ have a bridge capacitor (C₂) reduced to zero.

12. A device according to any of the claims 10 or 11, wherein the cells A₂, B₂ have a ground capacitor (C₁) reduced to a short circuit.

13. A device according to any of the claims 10 to 12, wherein the capacitor (C₁) of the cells A₁, B₁ is connected to the ground potential by a metallized hole.

14. A device according to any of the claims 10 to 13, wherein the inductors are connected to the ground potential by means of metallized holes.

15. A device according to one of the above claims, wherein the inductors (L₁, L₂) of the cells are imbricated spirals.

16. A device according to any of the claims 1 to 14, wherein the inductors are spirals superimposed with several metal levels.

17. A device according to either of the claims 15 or 16, wherein the spiral forming an inductor (L₂) is contained in the spiral forming the other inductor (L₁).

18. A device according to any of the claims 15 or 16, wherein the spirals are offset.

19. A device according to any of the claims 15 to 18, wherein the spirals are symmetrical with respect to an axis.

20. A device according to any of the claims 15 to 19, wherein the spirals are conductive tracks made on a substrate.

21. A device according to claim 20, wherein the substrate is made of gallium arsenide (GaAs).

22. A device according to any of the claims 20 or 21, wherein the tracks are made of gold.
